(19) United States
(12) Patent Application Publication
(10) Pub. No.: US 2005/0157575 A1
(43) Pub. Date: Jul. 21, 2005

(54) Storage device and method

(75) Inventors: Gerd K. Binnig, Wollerau (CH); Evangelos S. Eleftheriou, Zurich (CH); Christoph Hagleitner, Zug (CH)

Correspondence Address: F. CHAU & ASSOCIATES, LLC, 130 WOODBURY ROAD, WOODBURY, NY, 11797, US

(73) Assignee: INTERNATIONAL BUSINESS MACHINES CORPORATION

(21) Appl. No.: 10/999,351

(22) Filed: Nov. 30, 2004

(30) Foreign Application Priority Data
Dec. 3, 2003 (EP) 03405859.4

(51) Int. Cl. G11C 7/00

(52) U.S. Cl. 365/222

(57) ABSTRACT

A storage device is provided, comprising of a storage surface having perturbations representative of information stored in the storage device; a lever having at least one tip facing the storage surface and movable substantially parallel thereto; and a variable capacitor having a first plate and a second plate, the first plate being integral to the storage surface and the second plate being integral to the lever, wherein movement of the lever relative to the surface produces variation in the capacitance of the variable capacitor in response to the tip scanning across the perturbations of the surface.

### FIELD OF THE INVENTION

This invention relates to storage devices, and more particularly, this invention relates to probe-based storage devices.

### BACKGROUND OF THE INVENTION

In the field of this invention techniques are known that use nanometer-sharp tips for imaging and investigating the structure of materials down to the atomic scale. Such techniques include scanning tunnelling microscopy (STM) and atomic force microscopy (AFM), as described in Binnig, G. et al., “7×7 reconstruction on Si(111) resolved in real space,” Phys. Rev. Lett., 50 (1983) 120 (Binnig 1983); and Binnig, G. et al., “Atomic force microscope,” Phys. Rev. Lett., 56 (1986) 930 (Binnig 1986). Both STM and AFM are suitable for the development of ultrahigh-density storage devices, as discussed in U.S. Pat. No. 4,575,822 issued 11 Mar. 1986 to Quate, which discloses a digital memory in which data is stored by establishing perturbations in the surface of a substrate and thereafter identifying the perturbations by establishing a tunnel electron current between the surface of the substrate and a movable probe. In principle, both STM and AFM are suitable for the development of ultrahigh-density storage devices.

In STM a sharp tip is scanned in close proximity to a surface and a voltage applied between the tip and a sample gives rise to a tunnel current that depends on the tip-sample separation. From a data-storage viewpoint, such a technique may clearly be used to image or sense the deliberate topographic changes on a flat medium that represent the stored information in logical “O”s and “1”s. In order to achieve reasonable stable current, the tip-sample separation must be maintained extremely small and fairly constant. These characteristics impose serious constraints in implementing an active servo control with reasonable speed. The low tunnelling currents and feedback speed limit the data rate to rather low values. For these reasons most of the work in probe-based data storage schemes has focused on AFM implementations.

In AFM, the sharp tip sits at the end of a soft spring cantilever. In this way very small forces may be sensed. The tip may touch the surface of the medium, without necessarily destroying the tip or the surface of the medium. AFM may also operate in a non-contact mode, in which it reacts to forces exerted by the medium. The use of an AFM tip for reading-back and writing topographic features for data storage was demonstrated in Mamin, H. J. et al., “Thermomechanical writing with an atomic force microscope tip” Appl. Phys. Lett., 61, (1992) 1003-1005 (Mamin 1992). In a particular, according to the scheme described in Mamin 1992, reading and writing is performed with a single AFM tip in contact with a rotating polycarbonate or polymethyl methacrylate (PMMA) substrate. For performing thermomechanical writing a focused laser beam heats the optically absorbing tip. The heated tip softens the PMMA medium, and the local tip pressure creates an indentation. An external laser readout approach has been adopted for reading back the stored information.

However, in practical applications it is necessary to reduce the form factor so that the dimensions of standard small size memory cards, such as the ones used today with flash memory or the microdrive, may also be used for probe-based storage devices. There are currently various standards on the market for small size memory cards, for example known as secure digital (SD™), COMPACTFLASH™, multimedia memory card (MMC), etc. Other means that allow very large scale integration and miniaturization of the write and read back process are required. Known integrated probe storage devices, which allow for small form factor, rely primarily on thermal writing and thermal, piezoresistive, or piezoelectric sensing. For example, a concept of topographic data storage using an AFM tip in which the tip rides over the surface of the medium, causing deflection of the cantilever as it moves over the indentations representing the logical “O”s and “1”s, is described in Mamin, H. J. et al., “High-Density Data Storage Based on the Atomic Force Microscope”, Proc. IEEE, vol. 87, no. 6, pp. 1014-1027, June 1999 (Mamin 1999); and Mamin, H. J. et al., “Tip-based data storage using micromechanical cantilevers,” Sensors and Actuators A 48 (1995) 215-219 (Mamin 1995). The deflection is then detected via a piezoresistive sensor.

A typical example of such a probe-based storage device that uses thermomechanical writing and thermomechanical or thermal reading by using heater cantilevers is known as the millipede and disclosed in Vettiger et al., “The ‘Millipede’—More than one Thousand Tips for Future AFM Data-Storage,” IBM J. Res. Develop., Vol. 44, No. 3, pp. 323-340 (2000); and E. Eleftheriou et al., “Millipede-a MEMS-based scanning-probe data-storage system,” IEEE Trans. Magn., vol. 39, pp. 938-945 (2003). Such a system is also disclosed in U.S. Pat. No. 5835477 issued 10 Nov. 1998 to Binnig, G. K. et al. The heater cantilever originally used for writing is given the additional function of a thermal read back sensor by exploiting its temperature dependent resistance. U.S. Pat. No. 6,249,747 issued 19 Jun. 2001 to Binnig, G. K. et al. discloses an AFM probe that encompasses both functions of writing and reading to and from a storage medium. The relative variation of thermal resistance is on the order of 10⁻⁵ per nm. Hence, a written “1” typically produces a relative change of the cantilever thermal resistance of the order of ΔR/R=10⁻⁴ to 5×10⁻⁴. Note that the relative change of the cantilever electrical resistance is of the same order. Thus, one of the most critical issues in detecting the presence or absence of an indentation is the high resolution required to extract the signal that contains the information about the logical bit being “1” or “0”.

Sensitivity, power consumption, and size are critical issues for all aforementioned integrated sensing or read back approaches. For example, in piezoresistive sensing the main issues are the size of the sensor and its sensitivity in terms of the variation of the electrical resistance expressed as ΔR/R. Similarly, in Millipede, the main issues with thermomechanical or thermal sensing are power consumption, sensitivity in terms of variation of the thermal resistance and limitation on the data rate per lever due to the thermal time constant of the lever. Due to limitations regarding the data rate of a single cantilever, massive parallelization is needed to achieve high data rates.

Towards this end, dense 2-D cantilever arrays with integrated write/read functionality were proposed in U.S. Pat. No. 5,835,477. Writing and reading are done by time-multiplexing of the electronic signals that control the access of the cantilevers in one row or column of the 2-D array, as discussed in Vettiger, P. et al., “The Millipede—More than one thousand tips for future AFM data storage,” IBM Journal of Research and Development, vol. 44 NO. 3 May 2000, pp. 323-340. However, this approach has the disadvantages of limitations of single AFM sensors regarding sensitivity, power consumption, and read back data rate associated with previous approaches.

Another approach involves charge sensing. The general concept of charge sensing has found applications in various areas. Applications include subatomic particle detection, human presence detection, material analysis, fingerprint sensors, touch controls, product moisture sensing, etc. Micromachined sensors with integrated capacitive read-out circuitry have been developed for various applications, e.g. for accelerometers, fingerprint-sensors, and chemical sensors, as discussed respectively in Sherman, S. J. et al., “A Low-Cost Monolithic Accelerometer; Product/Technology Update” VLSI Circuits, 1992, Digest of Technical Papers, pp. 34-35; Tartagni, M. et al., “A Fingerprint Sensor Based on the Feedback Capacitive Sensing Scheme”, IEEE J. Solid State Circuits, vol. 33, pp. 133-142, January 1998; and Hagleitner, C. et al., “CMOS Capacitive Chemical Microsystem with Active Temperature Control for Discrimination of Organic Vapours”, Proc. Transducers '99, vol. 2, pp. 1012-1015, 1999.

In U.S. Pat. No. 6,172,506 issued 9 Jan. 2001 to Adderton et al., an AFM device is disclosed for measuring impurity concentration of semiconductors, where an electrically conductive tip operates in a tapping mode while a capacitive sensing circuit measures between the probe tip and the surface of a sample. However, the capacitance between the conductive tip and the surface of the sample is not constant. Additionally, the configuration is extremely difficult to implement in parallel operation which is required in probe-storage applications.

A need therefore exists for a storage device and method wherein the abovementioned disadvantages may be alleviated.

### STATEMENT OF INVENTION

A storage device is provided, comprising of a storage surface having perturbations representative of information stored in the storage device; a lever having at least one tip facing the storage surface and movable substantially parallel thereto; and a variable capacitor having a first plate and a second plate, the first plate being integral to the storage surface and the second plate being integral to the lever, wherein movement of the lever relative to the surface produces variation in the capacitance of the variable capacitor in response to the tip scanning across the perturbations of the surface.

A method of reading information in a storage device is also provided, comprising scanning a tip of a lever across a storage surface of the storage device, the tip facing the storage surface and movable substantially parallel thereto, the storage surface having perturbations representative of information stored in the storage device; and detecting a variation in capacitance with a variable capacitor having a first plate and a second plate, the first plate being integral to the storage surface and the second plate being integral to the lever, wherein movement of the lever relative to the surface produces variation in the capacitance of the variable capacitor in response to the tip.

### BRIEF DESCRIPTION OF THE DRAWINGS

One storage device and method incorporating the present invention will now be described, by way of example only, with reference to the accompanying drawings, in which:

FIG. 1 shows a cross-sectional view of a probe-based storage device;

FIG. 2 shows a top plan view of a probe in accordance with an embodiment of the invention;

FIG. 3 shows a cross-sectional view of a probe-based storage device in accordance with an embodiment of the invention;

FIG. 4 shows a cross-sectional view of a probe-based storage device in accordance with an embodiment of the invention;

FIG. 5 shows a cross-sectional view of a probe-based storage device in accordance with an embodiment of the invention;

FIGS. 6A and 6B show a circuit diagram and a phase diagram of the circuit in accordance with an embodiment of the invention;

FIG. 7 shows a circuit diagram in accordance with an embodiment of the invention;

FIGS. 8A and 8B show a circuit diagram and a phase diagram of the circuit in accordance with an embodiment of the invention; and

FIG. 9 shows a circuit diagram in accordance with an embodiment of the invention.

### DESCRIPTION OF PREFERRED EMBODIMENTS

An embodiment of the invention applies capacitive read-out to scanning probes, where optical, piezoresistive, or thermal read-out techniques are often used, for example, for sensing or reading back stored information in polymer media using a single sensor (cantilever) or a plurality of sensors (cantilevers) in a 2-D arrangement.

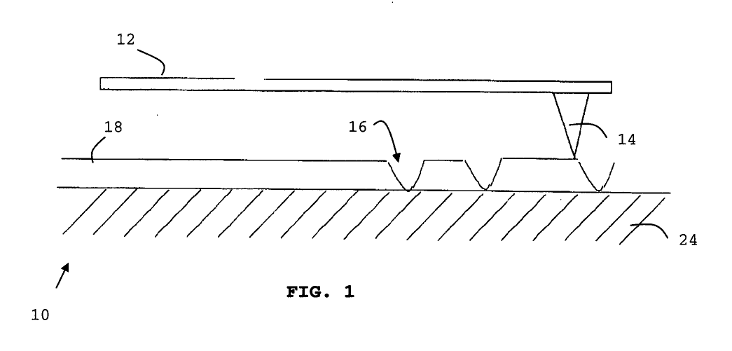

FIG. 1 shows the cross-section of a general probe-based storage device. The device comprises a scanning lever 12 such as a spring cantilever having a tip 14 at one end of the lever. The scanning lever is arranged to be sensitive to vertical forces, and contact a sample 18 such as a polymer media on a conducting substrate 24. The sample may have indentations 16 or marks that the tip of the lever traverses.

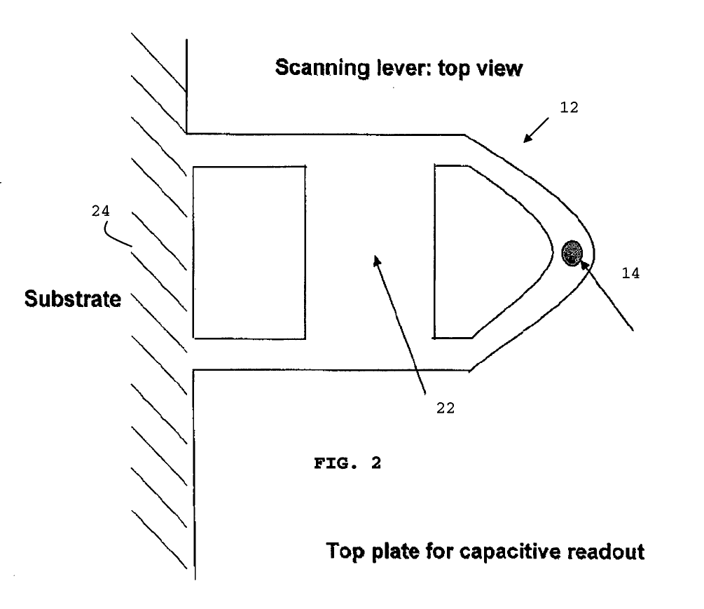

FIG. 2 shows the top plan view of a two-terminal probe or lever 12 in accordance with an embodiment of the invention that has the desired properties for capacitive sensing. The lever comprises the tip 14, and a capacitive platform 22 for enhanced capacitive force. This capacitive platform may also be used for capacitive readout as discussed in further detail below. Recent cantilever structures are based on a three-terminal design in which there are separate resistive heaters for reading and writing as well as the capacitive platform mentioned above. In both cases the main body of the cantilever consists of silicon (Si). The cantilever legs are attached to a rigid support structure. In thermomechanical probe-based storage, information is stored as sequences of indentations written in nanometer-thick polymer films using a 2D array of AFM cantilevers. Information is written by heating the tip and locally melting the polymer film, thus creating an indentation. The tip-medium spacing is controlled globally, and write/read operations depend on mechanical x/y scanning of the storage medium. Parallel operation is achieved by accessing all or a subset of the cantilevers simultaneously, which may yield high data rates. Scanning of the storage medium is achieved by a miniaturized scanner with x/y-motion capabilities on the order of the pitch between adjacent cantilevers in the array. The microscanner consists of, for example, a mobile platform, supported by springs that carry the polymer medium. Actuation in the x-direction and the y-direction may be achieved by applying a current to a coil positioned between a pair of miniature permanent magnets attached to the silicon scanner. In the drawings two levels of stored information is considered, i.e. “1” and “0” for indentation and non-indentation. It will be appreciated that multilevel symbols e.g., 0, 1, 2, . . . may be associated with corresponding indentation depths and achieve higher areal density by carrying more bits of information per symbol.

Additionally, for illustrative purpose, a 2D-array AFM probe storage is discussed which is based on a mechanical parallel x/y scanning of either the entire cantilever-array chip or the storage medium. It will be appreciated that the substrate, for example a silicon substrate, may be scanned with the sample, for example a polymer medium, on the substrate with the cantilever array, together with the interconnection to electronics, rigid. For an application such as thermomecanical probe storage the lever, tip, capacitive platform, and substrate may be silicon whereas the medium may be a polymer. In an embodiment, the cantilever may have a conducting platform, or a layer stack of different material, but the rest of the lever may be of any other material, for example silicon-nitride. Additionally, the medium is not required to be a polymer as long as there exists a conducting layer underneath.

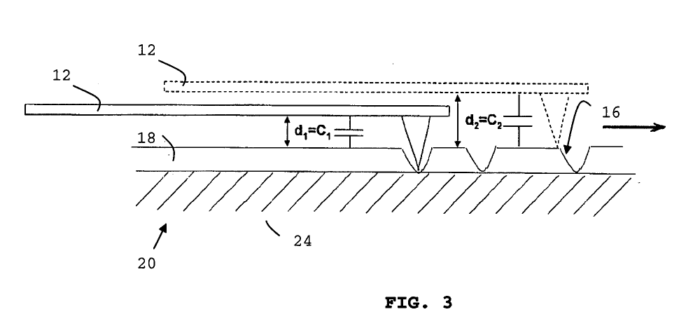

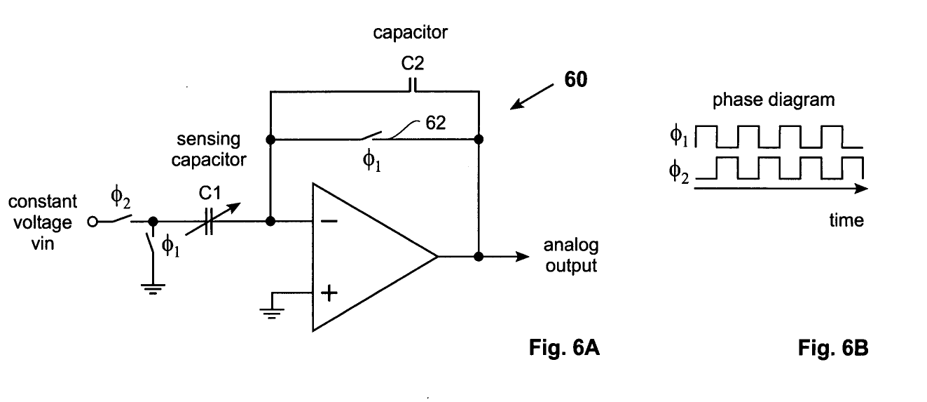

Referring to FIG. 3, according to an embodiment of the invention the sensing probe 12 is always in contact with the media during the readout process. In this case the capacitance between the probe and the conducting substrate changes when the tip traverses into an indentation 16 of the media. Thus, the probe moves along the surface of the sample in, as indicated by the lever, and out, as indicated by the dashed lever, of an indentation 16. This causes a difference in the distance the scanning lever 12 is relative to the conducting substrate 24, as indicated by d₁ and d₂, which translates to a capacitance change, as indicated by C₁ and C₂. This change in capacitance is detected by a capacitor sensing circuit, as shown for example in FIG. 6 discussed in detail below, during readout to provide a voltage signal representative of a stored information symbol.

In another embodiment, the tip is not always in contact with the medium, for example, a writing force may be exerted on the tip via the capacitive platform to contact the tip with the medium during each write pulse. The duration of the force pulse may be chosen to extend slightly beyond the termination of the heating pulse. This writing mode of operation is intermittent-contact mode, which of course may also be used during a read operation.

According to another embodiment a conducting plate is placed firmly on top of the flexible scanning probe cantilever. The conducting plate or electrode fixed above the lever may “travel” with the lever or it may be fixed relative to the conducting substrate. The basic principle of operation is similar to the one described in conjunction with the above embodiment; however, the difference in the distance is between the conducting plate that is fixed to the lever, and the conducting substrate 24, as indicated by d₁ and d₂, which translates to a capacitance change, as indicated by C₁ and C₂.

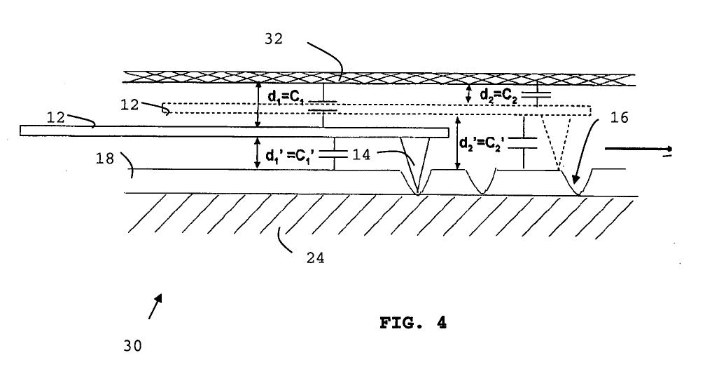

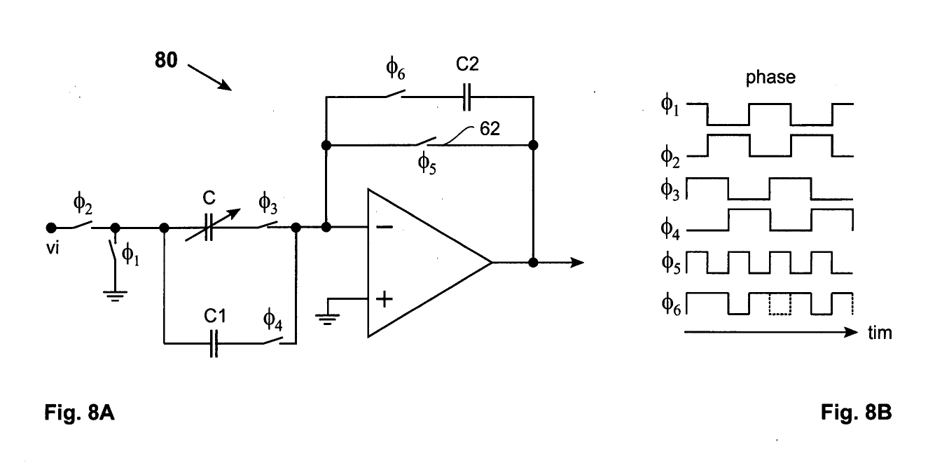

According to another embodiment of the variable capacitor arrangement 30 shown in FIG. 4, a conducting plate 32 is fixed relative to the substrate 24. The scanning probe cantilever 12 is positioned between the conducting plate and the substrate. The substrate, that the sample 18 is on, is a conducting substrate. This arrangement allows for differential sensing, for example a capacitive half bridge. The difference in the distance the scanning lever 12 is relative to the conducting plate 32 is indicated by d₁ and d₂, which translates to a capacitance change, as indicated by C₁ and C₂. The difference in the distance the scanning lever 12 is relative to the conducting substrate 24 is indicated by d₁′ and d₂′, which translates to a capacitance change, as indicated by C₁′ and C₂′. This change in capacitance is detected by a capacitor sensing circuit, as shown for example in FIG. 8A discussed in detail below, during readout to provide a voltage signal representative of a stored information symbol.

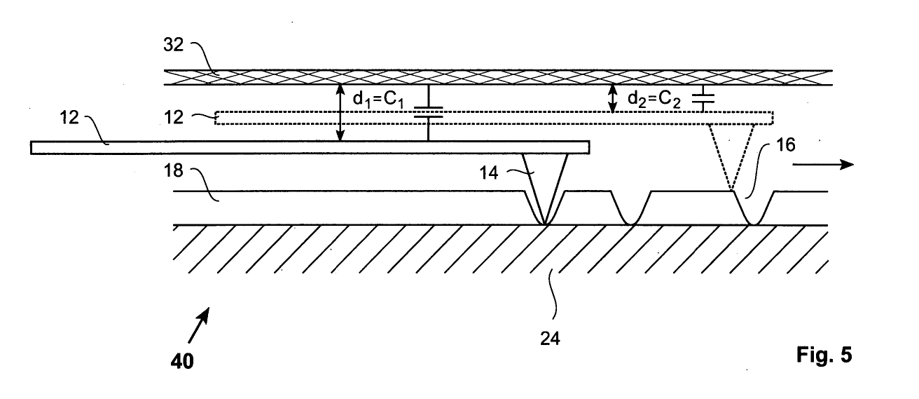

FIG. 5 shows another embodiment of the variable capacitor arrangement 40 in which only the capacitance between the cantilever 12 and the immobile top-plate 32 is assessed. The substrate 24 or sample 18 does not necessarily need to be conductive in this embodiment.

Each embodiment discussed may be extended for arrays of probes. The parallel read-out of several probes resolves the data-rate limitations of single scanning-probe-based storage devices. In one embodiment, the cantilevers share the same substrate electrode. This avoids the need for structuring of the substrate electrode. In another embodiment, the top plate or electrode may be attached to the lever anchor and stud structure of the lever, and the plate or electrode may be fixed relative to the substrate over the entire array of levers.

Different approaches to monitor the capacitance change are described in the following description. It will be clearly appreciated that the exemplary embodiments may be modified according to widely accepted circuit design techniques. An embodiment shown in FIG. 6A shows a circuit 60 that uses a parasitic-insensitive switched-capacitor scheme to read-out the small changes of approximately 1 femto-farad (1*10⁻¹⁵ F.) compared to a total capacitance of approximately 30 femto-farad. The different switching phases are shown in the phase-diagram of FIG. 6B. When Φ1 is active, the sensing capacitor is discharged and the input offset of the amplifier is stored on the sensing capacitor C1. In the active phase of Φ2, the sensing capacitor is charged to the constant voltage Vin through the feedback capacitor C2. The input offset of the amplifier 62 is cancelled in this configuration. The resulting analog output voltage is Vin*C1/C2 and hence proportional to the sensing capacitor C1. By adding a switch in series with capacitor C2 and adapting the switching phases according to accepted circuit design techniques, the analog output voltage can be made proportional to the change of sensing capacitor C1 (analog output voltage is Vin*deltaC1/C2).

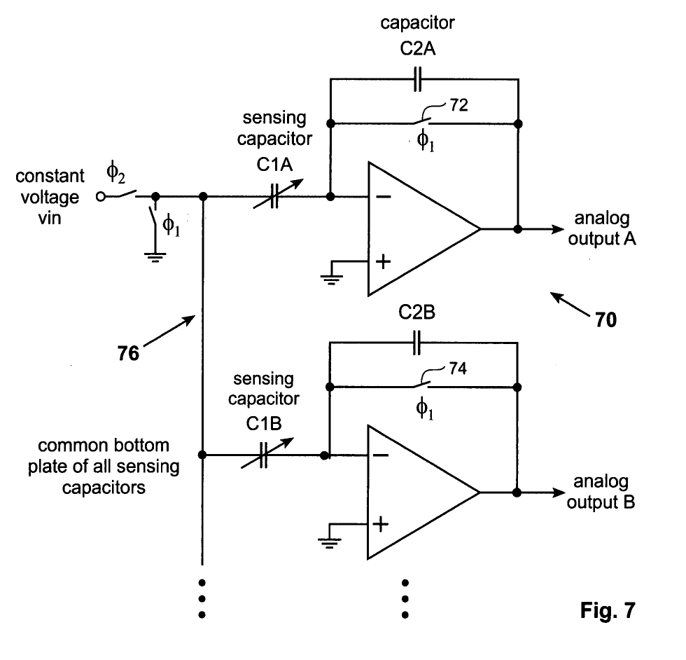

FIG. 7 is a circuit 70 showing how the implementation of FIG. 6A may be extended to read out an array of scanning-probes. The substrate (bottom plate) of the sensing capacitor is common 76 for all cantilevers and hence no structuring of the substrate is needed. When Φ1 is active, the sensing capacitors C1A and C1B are discharged and the input offset of the amplifier is stored on the sensing capacitors. In the active phase of Φ2, the sensing capacitors are charged to the constant voltage Vin through the feedback capacitors C2A and C2B. The input offsets of the amplifiers 72,74 are cancelled in this configuration. The resulting analog output voltages, i.e. analog output voltage A and analog output voltage B, are Vin*C1A/C2A and Vin*C1B/C2B and hence proportional to the sensing capacitors C1A and C1B.

FIG. 8A shows a configuration of circuit 80 where an immobile reference element C1′, which has similar size and properties, for example thermal coefficients, is used to perform a differential measurement. The analog output voltage is then given by Vin*(C1−C1′)/C2 and hence proportional to the difference between the sensing capacitor C1 and the immobile reference capacitor C1′. The phase diagram in FIG. 8B shows the switching sequence. This eliminates the offset and, therefore, reduces the accuracy requirements of subsequent Analog-to-Digital converter stages. If Φ6 is operated n-times according to the dotted line drawn in FIG. 8B, the analog output voltage is given by n*Vin*(C1−C1′)/C2. This way, an n-times amplification of the signal is achieved.

The configuration shown in FIG. 8A may also be used to read-out the differential arrangement shown in FIG. 4 and described above. In this case, the capacitance C1 corresponds to the capacitance between the top plate and the cantilever platform. Capacitance C1′ corresponds to the capacitance between the cantilever platform and the conducting substrate.

The configurations shown in FIG. 8A, FIG. 7, and FIG. 6A may be transformed into fully differential configurations according to widely accepted circuit design techniques. This reduces the sensitivity of the read-out circuit to power-supply noise and substrate noise.

When the capacitor formed by the cantilever plus substrate is charged using a constant DC-voltage the current to the capacitor may also be used to monitor the deflection of the cantilever when the tip falls into an indentation 16. This leads to an increase of the capacitance and a current flows, charging the capacitor even more. This current is only different from zero when the cantilever moves up or down with respect to the substrate. With an additional electrode on the backside of the cantilever this force may be balanced by charging this resulting cantilever as well.

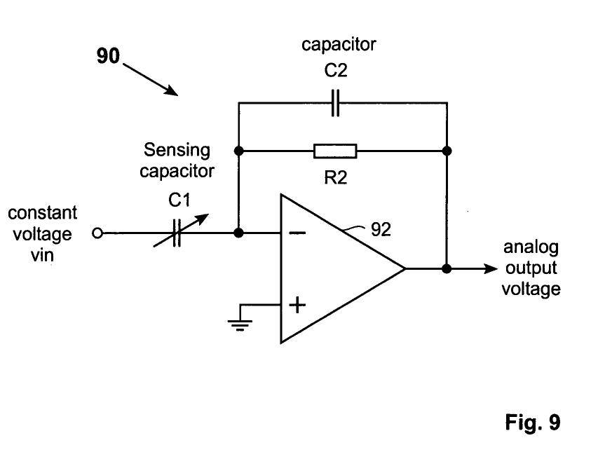

An embodiment of the read-out electronics for constant DC-voltage bias as described above is shown in a circuit 90 shown in FIG. 9. The embodiment places the sensor into a continuous time highpass filter and therefore has potentially superior noise-performance compared to the switched-capacitor embodiments. The highpass filter formed by R2 and C2 eliminates the effects of leakage-currents and low-frequency noise-sources. For frequencies larger than the highpass corner frequency, the analog output voltage is given by Vin*(C1/C2). Similar to the switched capacitor scheme, differential arrangements may be used to improve the performance.

It will be understood that the storage device and method described above provides the advantages of improved sensitivity, power consumption, and/or read back data rate. It will be appreciated that specific embodiments of the invention are discussed for illustrative purposes, and various modifications may be made without departing from the scope of the invention as defined by the appended claims.

1. A storage device, comprising:
a storage surface having perturbations representative of information stored in the storage device;
a lever having at least one tip facing the storage surface and movable substantially parallel thereto; and
a variable capacitor having a first plate and a second plate, the first plate being integral to the storage surface and the second plate being integral to the lever, wherein movement of the lever relative to the surface produces variation in the capacitance of the variable capacitor in response to the tip scanning across the perturbations of the surface.

2. The storage device of claim 1 further comprising a second variable capacitor comprising a third plate that is a fixed distance from the first plate, the second plate being positioned between the first and third plates, wherein movement of the lever relative to the third plate produces variation in the capacitance of the first and second variable capacitors in response to the tip scanning across perturbations of the surface.

3. The storage device of claim 2 wherein the first variable capacitor and the second variable capacitor provide a source for performing a differential measurement.

4. The storage device of claim 1 wherein the second plate is mechanically fixed to the lever.

5. The storage device of claim 1 further comprising a plurality of levers, each lever having a corresponding set of plates and tips forming a respective variable capacitor responsive to each respective tip scanning across perturbations of the surface.

6. The storage device of claim 1 wherein the perturbations of the surface are representative of multi-level symbols carrying more than one bit of information.

7. A method of reading information in a storage device, comprising:
scanning a tip of a lever across a storage surface of the storage device, the tip facing the storage surface and movable substantially parallel thereto, the storage surface having perturbations representative of information stored in the storage device; and
detecting a variation in capacitance with a variable capacitor having a first plate and a second plate, the first plate being integral to the storage surface and the second plate being integral to the lever, wherein movement of the lever relative to the surface produces variation in the capacitance of the variable capacitor in response to the tip.

8. The method of claim 7 further comprising detecting a variation in capacitance in a second variable capacitor, the second variable capacitor having a third plate that is a fixed distance from the first plate, the second plate being positioned between the first and third plates, wherein movement of the lever relative to the third plate produces variation in the capacitance of the first and second variable capacitors in response to the tip scanning across perturbations of the surface.

9. The method of claim 8 further comprising performing a differential measurement wherein the first variable capacitor and the second variable capacitor provide a source for performing the differential measurement.

10. The method of claim 7 wherein the second plate is mechanically fixed to the lever.

11. The method of claim 7 wherein the step of scanning further comprises scanning with a plurality of levers having a corresponding a tip, and the step of detecting further comprises detecting variations in capacitance in response to each tip scanning across perturbations of the surface.

12. The method of claim 7 wherein the perturbations of the surface are representative of multi-level symbols carrying more than one bit of information.
